(19) United States
(12) Patent Application Publication
(10) Pub. No.: US 2023/0015507 A1
(43) Pub. Date: Jan. 19, 2023

(54) Cable with Signal Detection Function

(71) Applicant: DongGuan City TuoCheng Industries Co., Ltd., Dongguan City (CN)

(72) Inventors: Quanyu Cai, Dongguan City (CN); Juntuo Yang, Dongguan City (CN); Siwei Zhu, Dongguan City (CN)

(21) Appl. No.: 17/394,895

(22) Filed: Aug. 5, 2021

(30) Foreign Application Priority Data
Jul. 15, 2021 (CN) 202121615602.X

(51) Int. Cl. H01B 7/18; G01R 31/58; H01B 9/02

(52) U.S. Cl. CPC H01B 7/1805; G01R 31/58; H01B 9/02; H01B 7/0009

(57) ABSTRACT

A cable with a signal detection function includes an insulating core, a second insulating layer, and a signal detection layer. The signal detection layer is for transmitting signal data. The cable further includes a second insulating layer, and plural signal detection layers provided for transmitting signal data. The signal detection layer and the insulating cores are disposed inside the second insulating layer, and the signal detection layer is cladded with plural insulating cores. If the first insulating layer in the signal detection layer is damaged, the signal detection layer will be electrically connected to the conductor assembly. The cable with the signal detection function can detect the abnormality of the insulating core through the signal detection layer to facilitate maintaining and repair the cable.

### FIELD OF THE INVENTION

The present invention relates to connection lines, and more particularly to a cable with a signal detection function.

### BACKGROUND OF THE INVENTION

Cable is an indispensable signal transmission device in daily life. It is necessary to use the cable in various electronic products such as power grids as a connector for signal transmission or power supply. Although the present existing cables are relatively durable and less affected by external factors, the cables may still be damaged during use. If the damaged cable cannot be detected timely, then it will paralyze the grids, affect people's safety, or cause damages to electronic products. At present, there are some cable structures on the market that can detect whether the interior of the cable is damaged, but these structures require the installation of a sensor or an inductive transmission device such as a Bluetooth device which is not practical since the interior space of the cable is limited and too many installed devices will affect the design of the cable and increase the cost of the cable, and thus these cable structures are not suitable for a large-scale use.

### SUMMARY OF THE INVENTION

In view of the drawbacks of the conventional cables, the present invention provides a cable with a signal detection function which can detect the abnormality of a conductor assembly through a signal detection layer in order to facilitate the maintenance of the cable timely.

To overcome the drawbacks of the prior art, the present invention discloses a technical solution and provide a cable with a signal detection function, comprising a plurality of insulating cores, each having a conductor assembly and a first insulating layer covering the outer periphery of the conductor assembly, characterized in that the cable further comprises a second insulating layer and a plurality of signal detection layers, and the signal detection layer being provided for transmitting signal data, and the signal detection layer and the plurality of insulating cores are disposed in the second insulating layer; and the signal detection layer is cladded with the plurality of insulating cores, and if the first insulating layer in the signal detection layer is damaged, the signal detection layer will be electrically coupled to the conductor assembly.

Preferably, the signal detection layer is cladded with at least two of the insulating cores, and the first insulating layer disposed inside the signal detection layer abuts against the inner wall of the signal detection layer.

Preferably, the signal detection layer is a synthetic graphene layer.

Preferably, the first insulating layer disposed outside the signal detection layer abuts against the outer periphery of the signal detection layer.

Preferably, the outer periphery of the insulating core disposed outside the signal detection layer is cladded with a signal mask layer.

Preferably, the signal mask layer is a synthetic graphene layer.

Preferably, there are three conductor assemblies.

Preferably, the conductor assembly comprises a plurality of conductive wires.

Preferably, the conductive wire is a copper wire, an enameled copper wire, or a nickel-clad copper wire.

Preferably, the cross-section of the conductive wire perpendicular to the lengthwise direction of the conductive wire is in a circular shape.

The present invention has the following advantages:

1. If the first insulating layer cladded by the signal detection layer is damaged or cracked, then the conductor assembly will be exposed from the first insulating layer, and the conductor assembly will be electrically connected to the signal detection layer to generate a short-circuit signal, and the signal detection layer will timely transmit the short-circuit signal to an external monitor, so as to maintain the cable timely.

2. The signal detection layer can be used for transmitting signal, so that it can produce a mask effect to the conductor assembly.

3. The structure of the present invention is simple and capable of completing the transmission and detection of the signals without requiring the installation of any extra sensor, and thus the structure of the invention is highly practical.

### BRIEF DESCRIPTION OF THE DRAWINGS

FIG. 1 is a schematic view of the structure of a first embodiment of this invention;

FIG. 2 is another schematic view of the structure of the first embodiment of this invention;

FIG. 3 is a schematic view of the structure of a second embodiment of this invention;

FIG. 4 is a cross-sectional view of FIG. 3;

FIG. 5 is a schematic view of the structure with a plurality of first insulating layers and a conductor assembly cladded in a signal detection layer in accordance with the second embodiment of the present invention;

FIG. 6 is a schematic view of the structure with a plurality of signal detection layer in accordance with the second embodiment of this invention; and

FIG. 7 is a schematic view of the structure of a third embodiment of this invention.

### BRIEF DESCRIPTION OF NUMERALS USED IN THE DRAWINGS

1—Conductor assembly, 2—First insulating layer, 3—Second insulating layer, 4—Signal detection layer, 5—Signal mask layer, and 6—Conductive wire.

### DESCRIPTION OF THE PREFERRED EMBODIMENTS

The technical contents of the present invention will become apparent with the detailed description of preferred embodiments accompanied with the illustration of related drawings as follows. It is intended that the embodiments and figures disclosed herein are to be considered illustrative rather than restrictive.

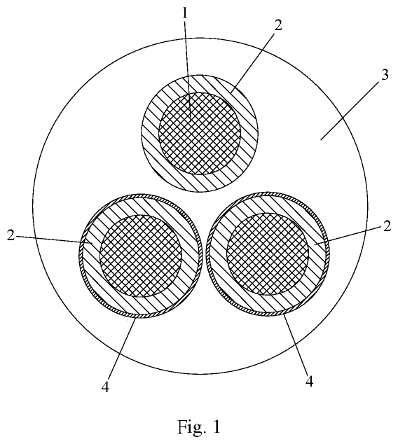

With reference to FIG. 1 for a cable with a signal detection function in accordance with the first embodiment of the present invention, the cable comprises a plurality of insulating cores, each having a conductor assembly 1 and a first insulating layer 2 cladded in the outer periphery of the conductor assembly 1. The cable further comprises a second insulating layer 3 and a plurality of signal detection layers 4, and the signal detection layer 4 is provided for transmitting signal data; the signal detection layer 4 and the plurality of insulating cores are disposed in the second insulating layer 3; the signal detection layer 4 is cladded with a plurality of insulating cores, and if the first insulating layer 2 inside the signal detection layer 4 is damaged, the signal detection layer 4 will be electrically coupled to the conductor assembly 1.

Specifically, when the structure of this embodiment is applied to a power cable, the power cable includes three insulating cores: a live line, a ground line and a neutral line. In this embodiment, the outer peripheries of two of the insulating cores are cladded with a signal detection layer 4. In general, the outer peripheries of the live and neutral lines are cladded with the signal detection layer 4, so that if the first insulating layer 2 of the live line or the neutral line is cracked or damaged, then the conductor assembly 1 in the first insulating layer 2 will be electrically coupled to the signal detection layer 4 to generate a short-circuit signal, and then the signal detection layer 4 will transmit the short-circuit signal to an external monitor to prompt that there is a failure inside the power cable, so as to facilitate technicians or related staffs to maintain or replace the power cable and reduce the chance of electrical accidents.

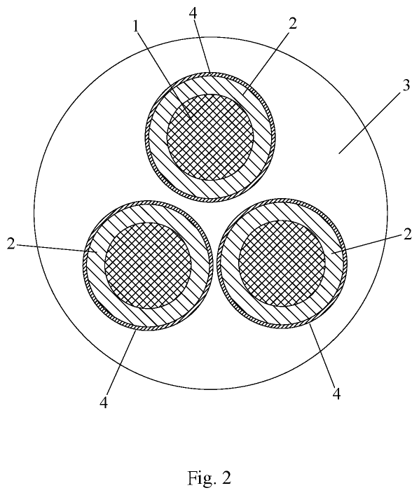

Further, when this embodiment is applied to other cables, signal detection layer 4 can be cladded on the outer periphery of all insulating cores as shown in FIG. 2.

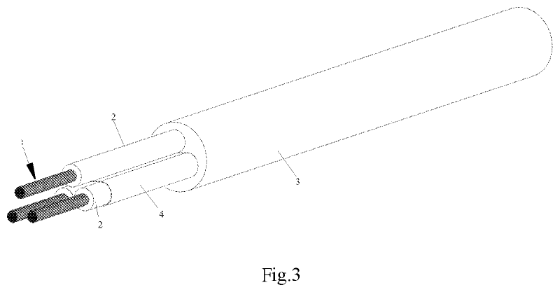

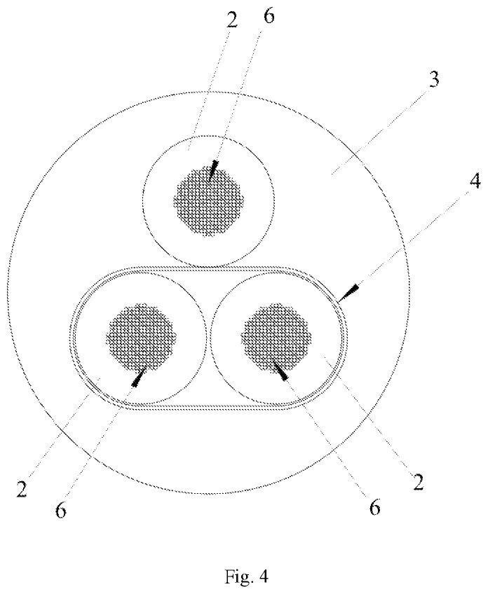

With reference to FIGS. 3 and 4 for a cable with a signal detection function in accordance with the second embodiment of the present invention, the signal detection layer 4 is cladded with at least two insulating cores, and the first insulating layer 2 disposed in the signal detection layer 4 abuts against the inner wall of the signal detection layer 4. If the first insulating layer 2 in the signal detection layer 4 is damaged, the signal detection layer 4 will be electrically coupled to the conductor assembly 1, wherein there are preferably at least three conductor assemblies 1.

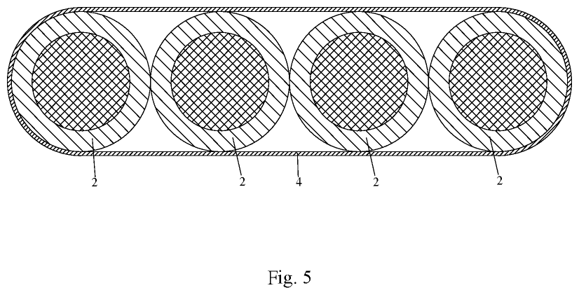

In FIG. 4, the other periphery of each conductor assembly 1 is cladded with the first insulating layer 2 to form the insulating core, and the insulating cores will not interfere with each other, and the signal detection layer 4 of this embodiment has the electrically conductive property and is capable of transmitting signals, and thus it also belongs to the mask layer of the insulating core. In this embodiment, at least two insulating cores is cladded with the signal detection layer 4, and the two insulating cores abut against each other, and there is at least one abutting point between the signal detection layer 4 and the insulating core cladded with the signal detection layer. To clad the insulating core tightly in a practical application, the structure as shown in FIGS. 4 and 5 is designed, wherein the semi-circumference of the insulating core actually abuts against both ends of the signal detection layer 4, so that the signal detection layer 4 can achieve the effect of transmitting and detecting signals with the smallest possible area to lower costs. When one or more first insulating layers 2 in the signal detection layer 4 are damaged, the conductor assembly 1 cladded with the first insulating layer 2 has a higher chance of exposing from the first insulating layer 2 and forming a short circuit between the conductor assembly 1 and the conductor assembly 1 and contacting with the signal detection layer 4 to generate a short-circuit signal, and the signal detection layer 4 will transmit the short-circuit signal to an external monitor, so as to facilitate technicians or related personnel to know about the situation and take corresponding actions timely and reduce losses. Compared with the insulating core cladded with the signal detection layer 4 on its outer periphery, the signal detection layer 4 of this embodiment contains at least two insulating core installed therein to reduce the use of manufacturing materials of the signal detection layer 4 as shown in FIG. 5. When there are two or more insulating cores, the periphery of the insulating core no longer need to clad the signal detection layer 4, so that the manufacturing cost of the signal detection layer 4 can be lowered significantly.

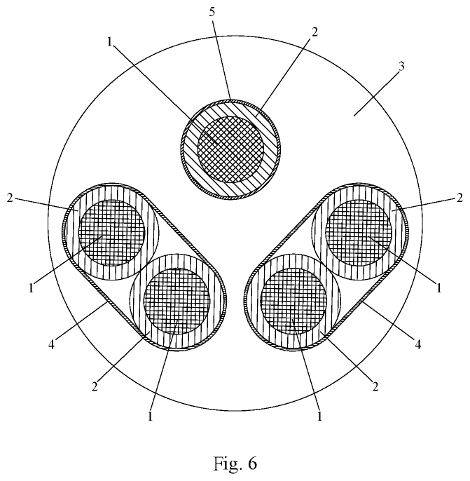

Of course, there may be a plurality of signal detection layers 4 in this embodiment as shown in FIG. 6.

Preferably, the signal detection layer 4 of this embodiment is a synthetic graphene layer. In other words, the signal detection layer 4 is made of graphene, and the graphene layer of this embodiment is manufactured by synthesis, but not by spraying.

This embodiment provides a cable with a signal detection function as shown in FIG. 4, and the first insulating layer 2 disposed outside the signal detection layer 4 abuts against the outer periphery of the signal detection layer 4.

Specifically, the periphery of the first insulating layer 2 is preferably configured to be abutting against the signal detection layer 4, so that if the first insulating layer 2 at the periphery is cracked or damaged, the exposed conductor assembly 1 and the signal detection layer 4 can generate a short-circuit signal, and the signal detection layer 4 transmits the short-circuit signal to an external monitor to facilitate maintaining the cable timely. This embodiment uses a signal detection layer 4 to detect a plurality of insulating cores, so that the cable of this embodiment has the features of a simpler structure and a lower cost. During practical applications, the insulating core outside the signal detection layer is also possibly not contacted with the signal detection layer. For example, if the external insulating core is a ground line, the cable can be designed without any contact point according to the actual situation.

This embodiment provides a cable with a signal detection function as shown in FIGS. 3 and 4, and the conductor assembly 1 comprises a plurality of conductive wires 6, not just can be formed into a standalone conductive wire 6 only, but also can be twisted and braided into a conductor assembly 1 as well, wherein the conductive wire 6 is a copper wire, an enameled copper wire or a nickel-clad copper wire that can improve the durability and conductivity of the conductive wire 6. Preferably, the cross-section of the conductive wire 6 perpendicular to the lengthwise direction of the conductive wire is in a circular shape. Of course, a rectangular shape or any other shape can be adopted according to actual situations.

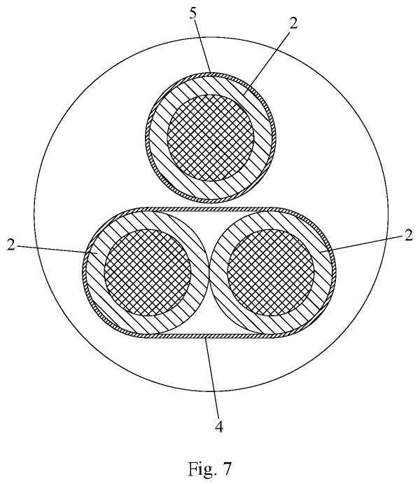

With reference to FIG. 7 for a cable with a signal detection function in accordance with the third embodiment of the present invention, the outer periphery of the first insulating layer 2 disposed outside the signal detection layer 4 is cladded with a signal mask layer 5. Preferably, the signal mask layer 5 is also a synthetic graphene layer.

Specifically, the periphery of the insulating core of the signal detection layer 4 of this embodiment has a signal mask layer 5 made of synthetic graphene and can achieve the effects of masking as well as detecting damages of the insulating core and transmitting signals.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A cable with a signal detection function, comprising a plurality of insulating cores, each having a conductor assembly and a first insulating layer covering the outer periphery of the conductor assembly, characterized in that the cable further comprises a second insulating layer and a plurality of signal detection layers, and the signal detection layer being provided for transmitting signal data, and the signal detection layer and the plurality of insulating cores are disposed in the second insulating layer; and the signal detection layer is cladded with the plurality of insulating cores, and if the first insulating layer in the signal detection layer is damaged, the signal detection layer will be electrically coupled to the conductor assembly.

2. The cable with a signal detection function according to claim 1, wherein the signal detection layer is cladded with at least two of the insulating cores, and the first insulating layer disposed inside the signal detection layer abuts against the inner wall of the signal detection layer.

3. The cable with a signal detection function according to claim 1, wherein the signal detection layer is a synthetic graphene layer.

4. The cable with a signal detection function according to claim 3, wherein the first insulating layer disposed outside the signal detection layer abuts against the outer periphery of the signal detection layer.

5. The cable with a signal detection function according to claim 1, wherein the outer periphery of the insulating core disposed outside the signal detection layer is cladded with a signal mask layer.

6. The cable with a signal detection function according to claim 5, wherein the signal mask layer is a synthetic graphene layer.

7. The cable with a signal detection function according to claim 3, wherein the insulating cores come with a quantity of at least three.

8. The cable with a signal detection function according to claim 3, wherein the conductor assembly comprises a plurality of conductive wires.

9. The cable with a signal detection function according to claim 8, wherein the conductive wire is a copper wire, an enameled copper wire, or a nickel-clad copper wire.

10. The cable with a signal detection function according to claim 8, wherein the cross-section of the conductive wire perpendicular to the lengthwise direction of the conductive wire is in a circular shape.
